(19) United States
(12) Patent Application Publication
(10) Pub. No.: US 2026/0331377 A1
(43) Pub. Date: Oct. 22, 2026

(54) DEVICE AND METHOD FOR PRODUCING DEVICE

(71) Applicant: Tokyo Electron Limited, Tokyo (JP)

(72) Inventors: Tetsu OHTOU, Tokyo (JP); Koji WATANABE, Tokyo (JP); Tomonari YAMAMOTO, Tokyo (JP)

(73) Assignee: Tokyo Electron Limited, Tokyo (JP)

(21) Appl. No.: 19/695,001

(22) Filed: Jun. 2, 2026

Related U.S. Application Data
(63) Continuation of application No. PCT/JP2024/041897, filed on Nov. 27, 2024.

(30) Foreign Application Priority Data
Dec. 11, 2023 (JP) 2023-208447

(51) Int. Cl. H01G 4/30; H01G 4/008; H01G 4/12

(52) U.S. Cl. CPC H01G 4/30; H01G 4/008; H01G 4/12

(57) ABSTRACT

A device includes a substrate, a capacitor, a first contact, a second contact, a plurality of first insulating members, and a plurality of second insulating members. The capacitor is disposed on the substrate. The capacitor includes multilayer films stacked on each other, each of the multilayer films includes a first electrode film, an insulating film stacked on the first electrode film, and a second electrode film stacked on the insulating film. The first contact and the second contact penetrate the capacitor in a thickness direction of the capacitor. The plurality of first insulating members are disposed between the first contact and the second electrode films. The plurality of second insulating members are disposed between the second contact and the first electrode films.

### CROSS-REFERENCE TO RELATED APPLICATIONS

This application is a continuation application of international application No. PCT/JP2024/041897 having an international filing date of Nov. 27, 2024, and designating the United States, the international application being based upon and claiming the benefit of priority from Japanese Patent Application No. 2023-208447, filed on Dec. 11, 2023, the entire contents of each are incorporated herein by reference.

### TECHNICAL FIELD

Various aspects and embodiments of the present disclosure relate to a device and a method for producing a device.

### SUMMARY

An aspect of the present disclosure is a device including a substrate, a capacitor, a first contact, a second contact, a plurality of first insulating members, and a plurality of second insulating members. The capacitor is disposed on the substrate. The capacitor includes multilayer films stacked on each other, each of the multilayer films includes a first electrode film, an insulating film stacked on the first electrode film, and a second electrode film stacked on the insulating film. The first contact and the second contact penetrate the capacitor in a thickness direction of the capacitor. The plurality of first insulating members are disposed between the first contact and the second electrode film. The plurality of second insulating members are disposed between the second contact and the first electrode film.

### BRIEF DESCRIPTION OF DRAWINGS

FIG. 1 is a cross-sectional view illustrating an example of a structure of a device according to an embodiment of the present disclosure.

FIG. 2 is an enlarged cross-sectional view illustrating an example of an area in the vicinity of a first contact.

FIG. 3 is an enlarged cross-sectional view illustrating an example of an area in the vicinity of a second contact.

FIG. 4 is a flowchart illustrating an example of a method for producing the device.

FIG. 5 is a cross-sectional view illustrating an example of a device manufacturing process.

FIG. 6 is a cross-sectional view illustrating an example of the device manufacturing process.

FIG. 7 is a cross-sectional view illustrating an example of the device manufacturing process.

FIG. 8 is a cross-sectional view illustrating an example of the device manufacturing process.

FIG. 9 is a cross-sectional view illustrating an example of the device manufacturing process.

FIG. 10 is a cross-sectional view illustrating an example of the device manufacturing process.

FIG. 11 is a cross-sectional view illustrating an example of the device manufacturing process.

FIG. 12 is a cross-sectional view illustrating an example of the device manufacturing process.

FIG. 13 is a cross-sectional view illustrating an example of the device manufacturing process.

FIG. 14 is a cross-sectional view illustrating an example of the device manufacturing process.

FIG. 15 is a cross-sectional view illustrating another example of the structure of the device.

### DETAILED DESCRIPTION

Hereinafter, an embodiment of the disclosed device and method for producing a device will be described in detail based on the drawings. The following embodiment does not limit the disclosed device and method for producing a device.

To reduce a power source noise supplied to a semiconductor circuit, it may be desirable to dispose a decoupling capacitor having a larger capacitance closer to the circuit. PTL 1 discloses a technique of manufacturing a decoupling capacitor on a package substrate by using a semiconductor process.

A large-capacity capacitor may be also used for forming an analog circuit.

According to various aspects and an embodiment of the present disclosure, it is possible to provide a device including a capacitor with a large capacitance per unit area.

As a measure for increasing capacitance of a capacitor having a metal-insulator-metal (MIM) structure, it is conceivable to stack capacitors with the MIM structure in a vertical direction. To make electrodes facing each other with a dielectric layer interposed therebetween be a cathode and an anode, it is necessary to connect contact plugs that are not short-circuited to each other to the anode and the cathode, respectively. When one end of the capacitor with the MIM structure is formed in a stepped shape, and the contact plugs in a vertical direction connected to the electrodes are provided, the electrodes facing each other can be the cathode and the anode.

However, when one end of the capacitor with the MIM structure is formed in a stepped shape, a surface area of the dielectric layer is reduced by an amount by which the dielectric layer in a stepped portion is scraped, and the capacitance is reduced. When the number of stacked layers with the MIM structure increases, a region of a portion formed in a stepped shape increases along with the increase, and it is less likely to increase the capacitance per unit area of the capacitor having a region where the electrodes are disposed.

### Structure of Device 10

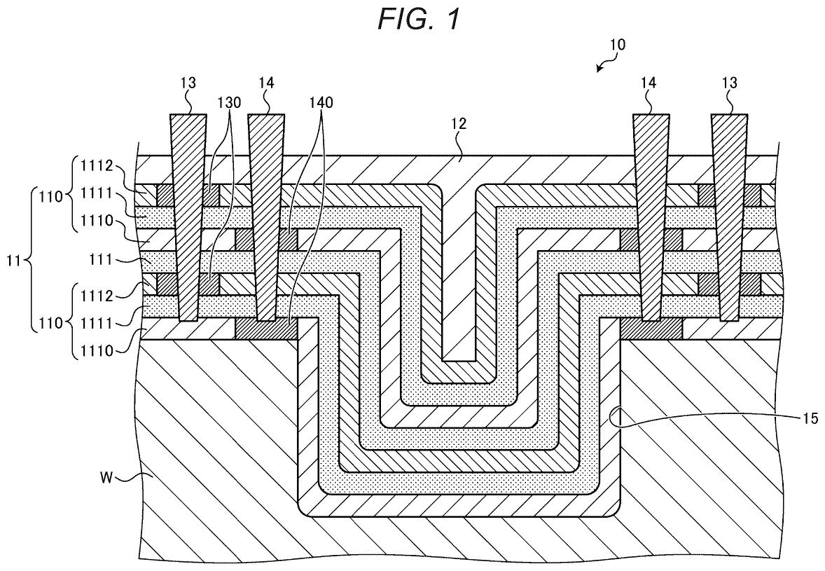

FIG. 1 is a cross-sectional view illustrating an example of a structure of a device 10 according to an embodiment of the present disclosure. The device 10 according to the present embodiment includes a substrate W, a capacitor 11 disposed on the substrate W, and a passivation layer 12 disposed on the capacitor 11. A part of the capacitor 11 is formed on the substrate W along a shape of a recess 15 formed in the substrate W.

The capacitor 11 includes multilayer films 110 stacked via an insulating film 111 (a dielectric). Each multilayer film 110 includes a first electrode film 1110, an insulating film 1111 (a dielectric), and a second electrode film 1112. The first electrode film 1110, the insulating film 1111, and the second electrode film 1112 are stacked in this order from a bottom of the multilayer film 110 to a top of the multilayer film 110, or from a top of the multilayer film 110 to a bottom of the multilayer film 110. The first electrode film 1110 is formed of, for example, a metal such as titanium nitride. The second electrode film 1112 is formed of, for example, a metal such as tungsten. The insulating films 111 and 1111 are formed of, for example, a dielectric such as hafnia, alumina, or zirconia.

The capacitor 11 provided in the device 10 illustrated in FIG. 1 includes two multilayer films 110. However, the technique disclosed herein is not limited thereto, and the capacitor 11 may include one hundred or more alternately stacked insulating films 111 and multilayer films 110.

In the present embodiment, the first electrode film 1110 preferably has a thickness of 1 nm or more and 100 nm or less. The insulating film 1111 preferably has a thickness of 1 nm or more and 100 nm or less. The second electrode film 1112 preferably has a thickness of 1 nm or more and 100 nm or less.

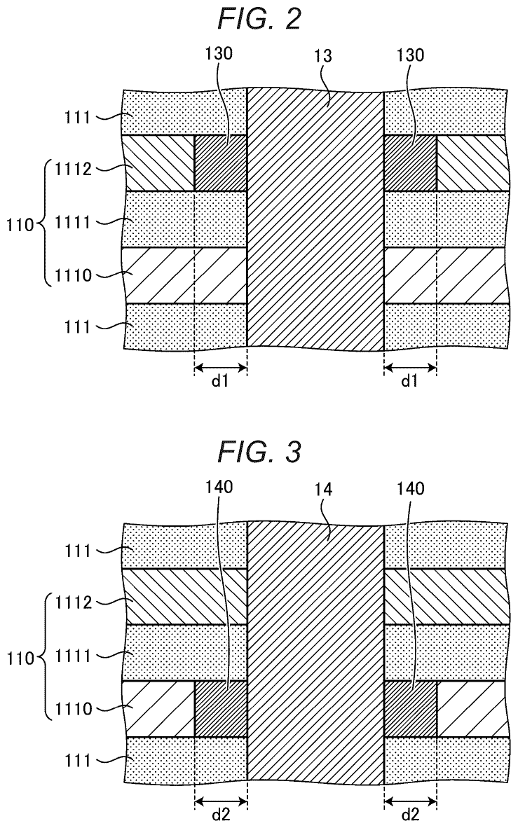

The capacitor 11 is provided with first contacts 13 and second contacts 14, each of the first contacts 13 and the second contacts 14 penetrating the capacitor 11 in a thickness direction of the capacitor 11. The first contacts 13 and the second contacts 14 are formed of, for example, a conductor such as titanium nitride, tungsten, or an impurity-doped semiconductor. As illustrated in, for example, FIG. 2, a first insulating member 130 is disposed between the first contact 13 and the second electrode film 1112. The first contact 13 and the second electrode film 1112 are insulated from each other by the first insulating member 130. A thickness d1 of the first insulating member 130 in a direction from the first contact 13 toward the second electrode film 1112 is preferably, for example, 1 nm or more and 100 nm or less. Accordingly, it is possible to prevent deterioration of the capacitance of the capacitor 11 while maintaining insulation between the first contact 13 and the second electrode film 1112, and between the second contact 14 and the first electrode film 1110. The first contact 13 and the first electrode film 1110 are in contact with each other, and the first contact 13 and the first electrode film 1110 are electrically connected to each other. When the capacitor 11 includes a plurality of multilayer films 110, the first contact 13 is in contact with, and electrically connected to, the first electrode film 1110 of each of the plurality of multilayer films 110, while being insulated from the second electrode film 1112 of each of the plurality of multilayer films 110 by the first insulating member 130.

As illustrated in, for example, FIG. 3, a second insulating member 140 is disposed between the second contact 14 and the first electrode film 1110. The second contact 14 and the first electrode film 1110 are insulated from each other by the second insulating member 140. A thickness d2 of the second insulating member 140 in a direction from the second contact 14 toward the first electrode film 1110 is preferably, for example, 1 nm or more and 100 nm or less. The second contact 14 and the second electrode film 1112 are in contact with each other, and the second contact 14 and the second electrode film 1112 are electrically connected to each other.

The first insulating member 130 and the second insulating member 140 are, for example, silicon oxide, silicon nitride, nitrogen-containing silicon oxide, carbon-containing silicon oxide, or carbon-and-nitrogen-containing silicon oxide.

In the device 10 according to the present embodiment, even when the number of multilayer films 110 stacked in the thickness direction of the capacitor 11 via the insulating film 111 increases, it is not necessary to increase regions where the first contact 13 and the second contact 14 are disposed. Therefore, by increasing the number of multilayer films 110 stacked in the thickness direction of the capacitor 11, it is possible to increase the capacitance per unit area of the capacitor 11.

### Manufacturing Method of Device 10

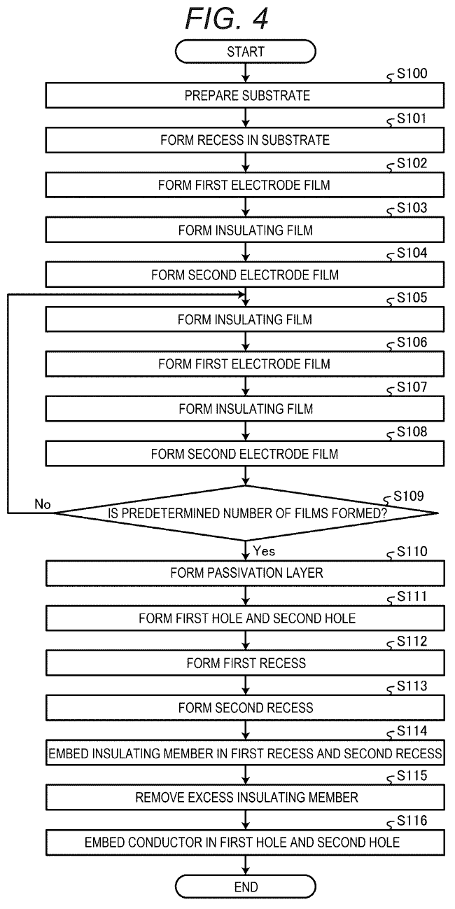

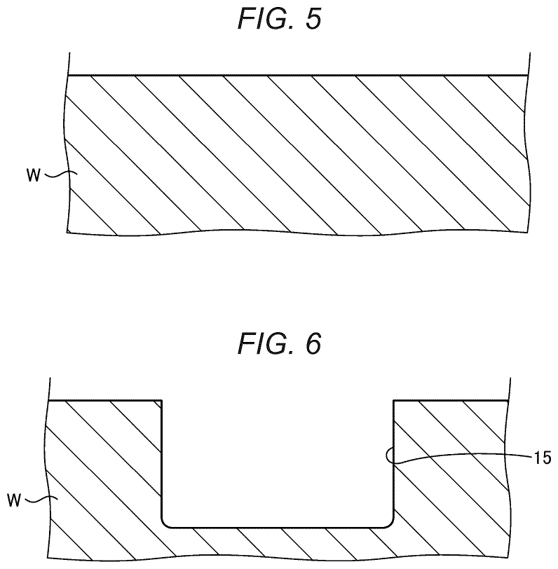

FIG. 4 is a flowchart illustrating an example of a manufacturing method of the device 10. Hereinafter, an example of the manufacturing method of the device 10 will be described with reference to FIGS. 5 to 14.

First, for example, the substrate W illustrated in FIG. 5 is prepared (step S100). The substrate W has, for example, a structure in which a silicon oxide film is formed on a silicon substrate.

Next, as illustrated in FIG. 6, for example, the recess 15 is formed in the substrate W (step S101). In step S101, the recess 15 is formed by lithography.

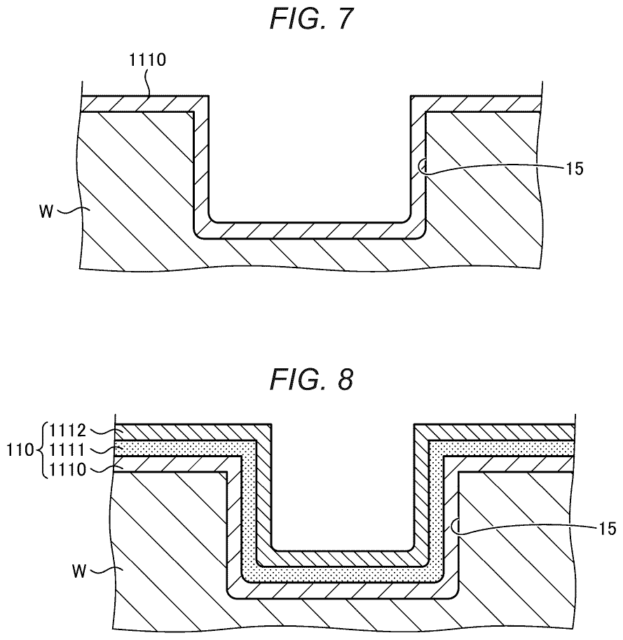

Next, for example, as illustrated in FIG. 7, the first electrode film 1110 is formed on the substrate W along the recess 15 in the substrate W (step S102). When the substrate W is conductive, an insulating film is inserted between the substrate W and the first electrode film 1110 to insulate the first electrode film 1110 from the substrate W. The first electrode film 1110 is formed by, for example, atomic layer deposition (ALD). When the first electrode film 1110 is titanium nitride, a titanium containing gas such as TiCl4 is used as a material gas, and a nitrogen containing gas such as NH3 is used as a modification gas.

Next, the insulating film 1111 is formed on the first electrode film 1110 (step S103). The insulating film 1111 is formed by, for example, ALD. When the insulating film 1111 is hafnia, for example, an organometallic material gas such as tetrakis(ethylmethylamino)hafnium is used as the material gas, and an oxygen containing gas such as ozone is used as the modification gas.

Next, the second electrode film 1112 is formed on the insulating film 1111 (step S104). The second electrode film 1112 is formed by, for example, ALD. When the second electrode film 1112 is tungsten, for example, a tungsten containing gas such as WF6 is used as the material gas, and a gas such as a silane gas or a hydrogen gas is used as the reaction gas. Accordingly, for example, as illustrated in FIG. 8, the multilayer film 110 including the first electrode film 1110, the insulating film 1111, and the second electrode film 1112 is formed on the substrate W along the shape of the recess 15.

Next, the insulating film 111 is formed on the second electrode film 1112 (step S105). As the insulating film 111, for example, hafnia can be used.

Next, the first electrode film 1110 is formed on the insulating film 111 (step S106), the insulating film 1111 is formed on the first electrode film 1110 (step S107), and the second electrode film 1112 is formed on the insulating film 1111 (step S108). Steps S106 through S108 thereby form another multilayer film 110 on the insulating film 111 formed in step S105. Then, it is determined whether a predetermined number of films is formed (step S109). When the device 10 illustrated in FIG. 1 is manufactured, in step S109, for example, it is determined whether two first electrode films 1110, two insulating films 1111, two second electrode films 1112, and one insulating film 111 are formed. The two first electrode films 1110, the two insulating films 1111, and the two second electrode films 1112 thereby form two multilayer films 110, and the one insulating film 111 is disposed between the two multilayer films 110, as illustrated in FIG. 1. When the predetermined number of films is not formed (No in step S109), the processing illustrated in step S105 is executed again.

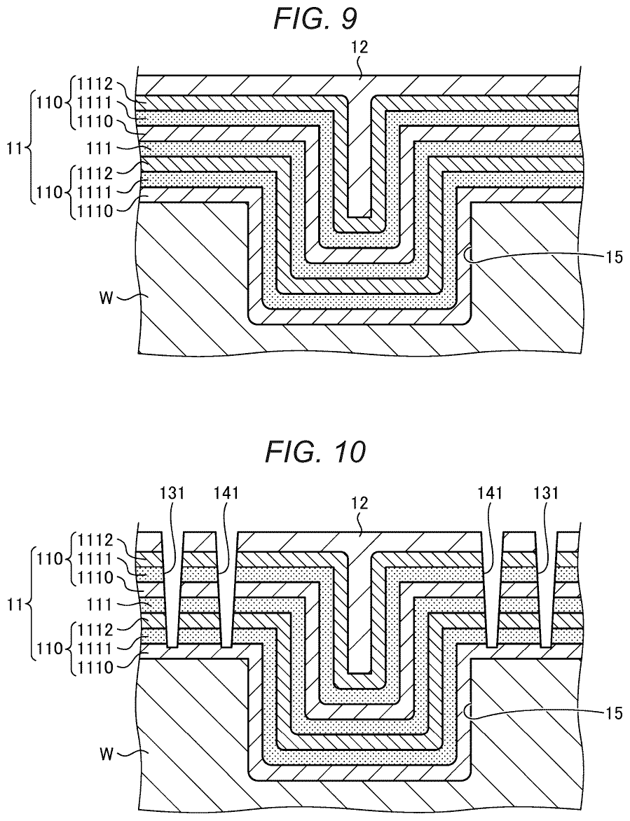

On the other hand, when the predetermined number of films is formed (Yes in step S109), the passivation layer 12 is formed on the second electrode film 1112 (step S110). Steps S102 to S109 are examples of step (a). Step S110 is an example of step (g), and the passivation layer 12 is an example of a protective film. Accordingly, for example, as illustrated in FIG. 9, the capacitor 11 is formed on the substrate W, and the passivation layer 12 is formed on the capacitor 11.

Next, for example, as illustrated in FIG. 10, first holes 131 and second holes 141 are formed (step S111). Step S111 is an example of step (b). In step S111, for example, the first holes 131 and the second holes 141 penetrating the capacitor 11 in the thickness direction of the capacitor 11 are formed by anisotropic dry etching. Bottoms of the first holes 131 and the second holes 141 preferably remain in the first electrode film 1110 and do not reach the substrate W.

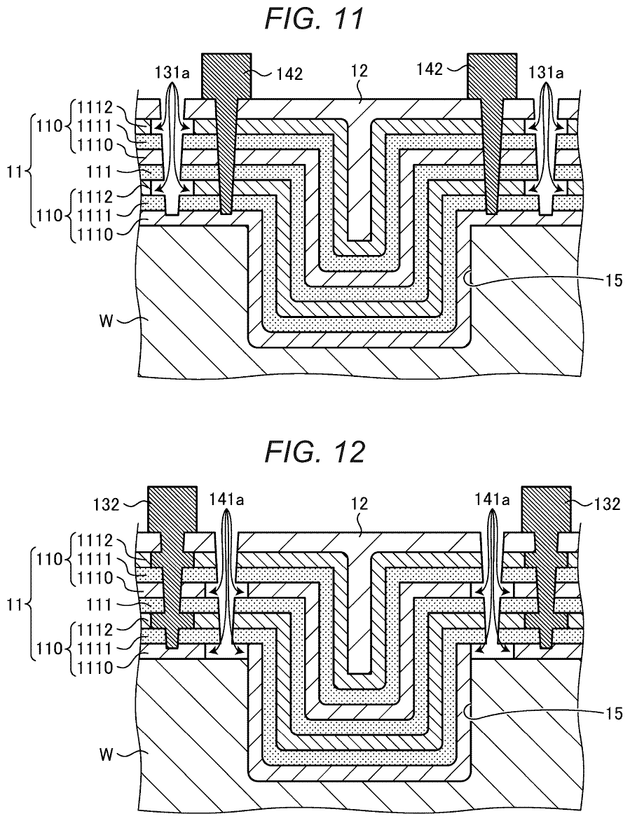

Next, the second electrode film 1112 exposed to a sidewall of the first hole 131 is etched to form a first recess 131a (step S112). Step S112 is an example of step (c). In step S112, for example, as illustrated in FIG. 11, after the second hole 141 is filled with a sacrificial film 142, an inside of the first hole 131 is exposed to an etching liquid. Accordingly, the second electrode film 1112 exposed to the sidewall of the first hole 131 is etched, and, for example, as illustrated in FIG. 11, the first recess 131a is formed in the sidewall of the first hole 131. The first recess 131a is recessed (i.e., extends) along an extending direction of the second electrode film 1112. A depth of the first recess 131a in the extending direction of the second electrode film 1112 is preferably, for example, 1 nm or more and 100 nm or less.

In step S112, a first etching liquid having a larger selectivity ratio for the second electrode film 1112 with respect to the first electrode film 1110 (an etching amount of the second electrode film 1112 is larger than that of the first electrode film 1110) is used. When the first electrode film 1110 is formed of, for example, titanium nitride, and the second electrode film 1112 is formed of, for example, tungsten, for example, an etching liquid containing orthoperiodic acid and water can be used as the first etching liquid. The etching liquid containing orthoperiodic acid and water is disclosed in, for example, JP2005-166924A, which indicates that tungsten can be etched with a large selectivity ratio with respect to titanium nitride.

Next, the first electrode film 1110 exposed to a sidewall of the second hole 141 is etched to form a second recess 141a (step S113). Step S113 is an example of step (d). In step S113, after the sacrificial film 142 in the second hole 141 is removed, for example, as illustrated in FIG. 12, the first hole 131 is filled with a sacrificial film 132, and an inside of the second hole 141 is exposed to the etching liquid. Accordingly, the first electrode film 1110 exposed to the sidewall of the second hole 141 is etched, and, for example, as illustrated in FIG. 12, the second recess 141a is formed in the sidewall of the second hole 141. The second recess 141a is recessed (i.e., extends) along an extending direction of the first electrode film 1110. A depth of the second recess 141 a in the extending direction of the first electrode film 1110 is preferably 1 nm or more and 100 nm or less.

In step S113, a second etching liquid having a larger selectivity ratio for the first electrode film 1110 with respect to the second electrode film 1112 (an etching amount of the first electrode film 1110 is larger than that of the second electrode film 1112) is used. When the first electrode film 1110 is formed of, for example, titanium nitride, and the second electrode film 1112 is formed of, for example, tungsten, for example, an etching liquid disclosed in JP2016-163044A can be used as the second etching liquid. The etching liquid disclosed in JP2016-163044A is a liquid containing (A) 75% by weight to 95% by weight of one or more selected from sulfuric acid and alkylsulfonic acid, (B) 0.3% by weight to 10% by weight of peroxide, (C) 0.0001% by weight to 3% by weight of an inorganic ammonium salt, and (D) a remainder of water, which indicates that titanium nitride can be etched with a large selectivity ratio with respect to tungsten.

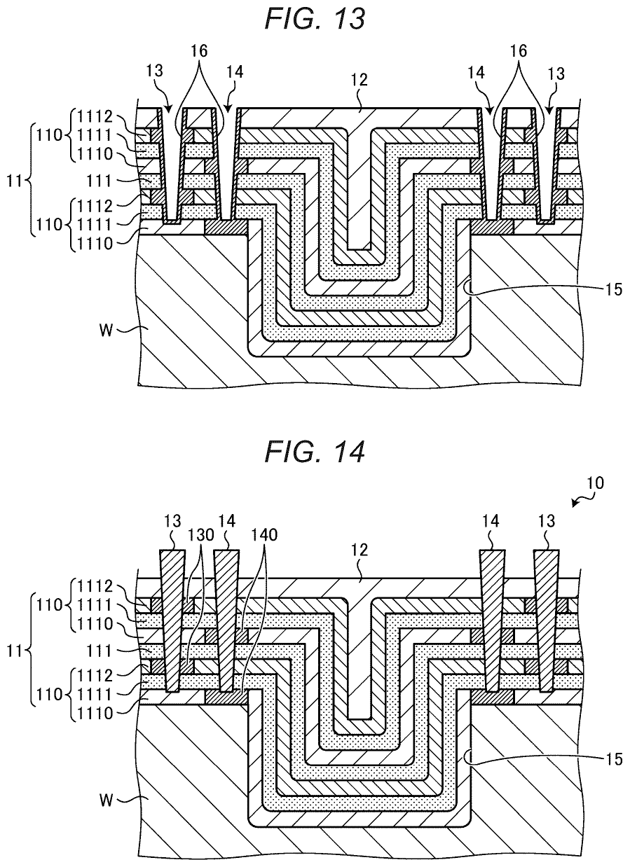

Next, insulating members are embedded in the first recess 131a and the second recess 141a (step S114). Step S114 is an example of step (e). In step S114, after the sacrificial film 132 in the first hole 131 is removed, the insulating member, which is a silicon containing member, is embedded in the first recess 131a and the second recess 141a by, for example, CVD. When the insulating member is silicon oxide, a silicon containing gas such as tetraethoxysilane (TEOS) is used as the material gas. Accordingly, for example, as illustrated in FIG. 13, insulating members 16 are embedded in the first recess 131a and the second recess 141a.

Next, the excess insulating member in the first hole 131 and the second hole 141 is removed (step S115). In step S115, an inside of the first hole 131 and an inside of the second hole 141 are each exposed to an etching liquid for etching a silicon oxide, which is the insulating member 16, for example, a third etching liquid such as hydrofluoric acid. Accordingly, the excess insulating member 16 formed on the sidewall of the first hole 131 and the sidewall of the second hole 141 except for the first recess 131a and the second recess 141a is removed, the first electrode film 1110 is exposed into the first hole 131, and the second electrode film 1112 is exposed into the second hole 141. The etching performed in step S115 is not limited to wet etching, and may be dry etching in which the silicon oxide film is isotropically removed.

Next, a conductor such as a metal is embedded in the first hole 131 and the second hole 141 (step S116), thereby forming the device 10. Step S116 is an example of step (f). In step S116, the metal is embedded in the first hole 131 and the second hole 141 by, for example, ALD. When the metal is titanium nitride, a titanium containing gas such as TiCl4 is used as the material gas, and a nitrogen containing gas such as NH3 is used as the modification gas. Accordingly, the metal is embedded in the first hole 131 and the second hole 141, and, for example, as illustrated in FIG. 14, the first contact 13 and the second contact 14 are formed. In the device 10 illustrated in FIG. 14, the first contact 13 and the first electrode film 1110 are electrically connected to each other, and the first contact 13 and the second electrode film 1112 are insulated from each other by the first insulating member 130 embedded in the first recess 131a. The second contact 14 and the second electrode film 1112 are electrically connected to each other, and the second contact 14 and the first electrode film 1110 are insulated from each other by the second insulating member 140 embedded in the second recess 141a. Then, the manufacturing method of the device 10 illustrated in the present flowchart is ended.

The embodiment has been described above. As described above, the device (the device 10) in the embodiment includes the substrate (the substrate W), the capacitor (the capacitor 11), the first contact (the first contact 13), the second contact (the second contact 14), the first insulating member (the first insulating member 130), and the second insulating member (the second insulating member 140). The capacitor is disposed on the substrate, and is obtained by stacking the multilayer films (the multilayer films 110) in each of which the first electrode film (the first electrode film 1110), the insulating film (the insulating film 1111), and the second electrode film (the second electrode film 1112) are stacked in this order. The first contact and the second contact penetrate the capacitor in a thickness direction of the capacitor. The first insulating member is disposed between the first contact and the second electrode film. The second insulating member is disposed between the second contact and the first electrode film. Accordingly, it is possible to provide the device 10 including the capacitor 11 with a large capacitance per unit area.

In the embodiment described above, the substrate has the recesses (the recesses 15). The first electrode film, the insulating film, and the second electrode film are disposed on the substrate in a shape along the recess. Accordingly, it is possible to further increase the capacitance per unit area of the capacitor 11.

In the embodiment described above, the thickness of the first insulating member in the direction from the first contact toward the second electrode film, and the thickness of the second insulating member in the direction from the second contact toward the first electrode film are both 1 nm or more and 100 nm or less. Accordingly, it is possible to prevent deterioration of the capacitance of the capacitor 11 while maintaining insulation between the first contact and the second electrode film and between the second contact and the first electrode film.

In the embodiment described above, the thickness of the first electrode film is 1 nm or more and 100 nm or less, the thickness of the second electrode film is 1 nm or more and 100 nm or less, and the thickness of the insulating film is 1 nm or more and 100 nm or less. Accordingly, it is possible to produce the capacitor 11 with a large capacitance in the device 10.

In the embodiment described above, the first electrode film is titanium nitride, and the second electrode film is tungsten. The insulating film is hafnia, alumina, or zirconia. Accordingly, it is possible to produce the capacitor 11 with a large capacitance in the device 10.

In the embodiment described above, the protective film (the passivation layer 12) is disposed on the capacitor. Accordingly, the capacitor 11 can be protected from members disposed on the capacitor 11.

The embodiment described above is a method for producing a device, and includes steps (a) to (f). In step (a), the capacitor obtained by stacking the multilayer films, in each of which the first electrode film, the insulating film, and the second electrode film are stacked in this order, is formed on the substrate. In step (b), the first hole (the first hole 131) and the second hole (the second hole 141) penetrating the capacitor in the thickness direction of the capacitor are formed. In step (c), the second electrode film exposed to the first hole is etched to form the first recess (the first recess 131a) recessed in the extending direction of the second electrode film. In step (d), the first electrode film exposed to the second hole is etched to form the second recess (the second recess 141a) recessed in the extending direction of the first electrode film. In step (e), the insulating member (the insulating member 16) is embedded in the first recess and the second recess. In step (f), the metal is embedded in the first hole and the second hole. Accordingly, it is possible to manufacture the device 10 including the capacitor 11 with a large capacitance per unit area.

In the embodiment described above, the recess is formed in the substrate, and in the step (a), the first electrode film, the insulating film, and the second electrode film are formed along the shape of the recess. Accordingly, it is possible to further increase the capacitance per unit area of the capacitor 11.

In the embodiment described above, the depth of the first recess in the extending direction of the second electrode film and the depth of the second recess in the extending direction of the first electrode film are both 1 nm or more and 100 nm or less. Accordingly, it is possible to prevent deterioration of the capacitance of the capacitor 11 while maintaining insulation between the first contact and the second electrode film and between the second contact and the first electrode film.

The method for producing a device in the embodiment described above further includes (g) forming the protective film on the capacitor. Accordingly, the capacitor 11 can be protected from members disposed on the capacitor 11.

### Other

The technology disclosed in the present application is not limited to the above-described embodiment, and various modifications are possible within the scope of the gist thereof.

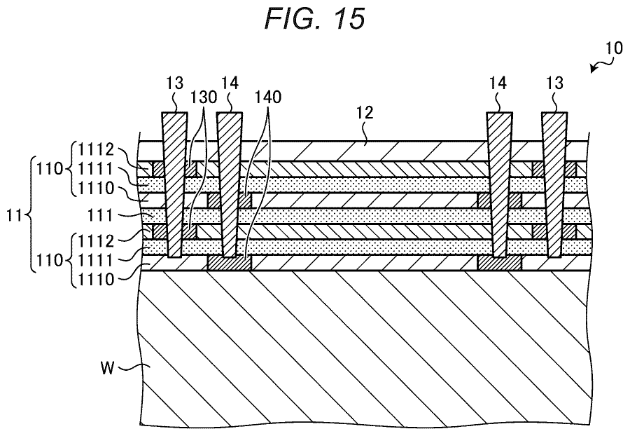

For example, in the embodiment described above, the capacitor 11 is formed along the shape of the recess 15 formed in the substrate W. However, the technique disclosed herein is not limited thereto. As another form, for example, as illustrated in FIG. 15, the capacitor 11 may be formed along a surface of a flat substrate W. Even in the device 10 having such a configuration, even when the number of multilayer films 110 stacked in the thickness direction of the capacitor 11 via the insulating film 111 increases, it is not necessary to increase the region where the first contact 13 and the second contact 14 are disposed. Therefore, by increasing the number of multilayer films 110 stacked in the thickness direction of the capacitor 11, it is possible to increase the capacitance per unit area of the capacitor 11.

In the embodiment described above, the first electrode film 1110 and the second electrode film 1112 are formed using titanium nitride and tungsten, respectively. However, the present disclosure is not limited thereto. As long as the first electrode film 1110 and the second electrode film 1112 are formed of materials capable of being etched with different selectivity ratios, the device can also be formed in the same manner as in the embodiment. The material need not be a metal either.

In the embodiment described above, for example, as illustrated in FIG. 1, the first contact 13 and the second contact 14 are disposed side by side in a direction along a paper surface. However, the technique disclosed herein is not limited thereto. As another form, the first contact 13 and the second contact 14 may be disposed side by side in a direction intersecting the paper surface (for example, in a direction orthogonal to each other). Accordingly, it is possible to reduce an area of the device 10 including regions where the first contact 13 and the second contact 14 are disposed.

In the embodiment described above, the capacitor 11 is formed along the shape of one recess 15 formed in the substrate W. However, the technique disclosed herein is not limited thereto. As another form, the capacitor 11 may be formed along shapes of the recesses 15 formed in the substrate W. Accordingly, it is possible to further increase the capacitance per unit area of the capacitor 11.

It shall be understood that the embodiments disclosed herein are illustrative and are not restrictive in all aspects. Indeed, the above-described embodiments can be implemented in various forms. The embodiments described above may be omitted, replaced, or modified in various forms without departing from the scope and spirit of the appended claims. Features, components, and method steps from any one embodiment described herein may be combined with features, components, and method steps from any other embodiment described herein to form additional embodiments within the scope of the present disclosure. All modifications and equivalents that come within the meaning and range of equivalency of the appended claims are intended to be embraced therein.

Further, the following appendixes will be further disclosed with respect to the above-described embodiment.

### Appendix 1

A device including:
a substrate,
a capacitor disposed on the substrate, the capacitor being obtained by stacking multilayer films in each of which a first electrode film, an insulating film, and a second electrode film are stacked in this order,
a first contact and a second contact penetrating the capacitor in a thickness direction of the capacitor,
a first insulating member disposed between the first contact and the second electrode film, and
a second insulating member disposed between the second contact and the first electrode film.

### Appendix 2

The device according to Appendix 1, in which
the first electrode film and the second electrode film are formed of different materials.

### Appendix 3

The device according to Appendix 1 or 2, in which
the first electrode film and the second electrode film are formed of materials capable of being etched at different selectivity ratios.

### Appendix 4

The device according to any one of Appendixes 1 to 3, in which
the substrate has a recess, and
the first electrode film, the insulating film, and the second electrode film are disposed on the substrate in a shape along the recess.

### Appendix 5

The device according to any one of Appendixes 1 to 4, in which
a thickness of the first insulating member in a direction from the first contact toward the second electrode film and a thickness of the second insulating member in a direction from the second contact toward the first electrode film are both 1 nm or more and 100 nm or less.

### Appendix 6

The device according to any one of Appendixes 1 to 5, in which
a thickness of the first electrode film is 1 nm or more and 100 nm or less,
a thickness of the second electrode film is 1 nm or more and 100 nm or less, and
a thickness of the insulating film is 1 nm or more and 100 nm or less.

### Appendix 7

The device according to any one of Appendixes 1 to 6, in which
the first electrode film is titanium nitride and
the second electrode film is tungsten.

### Appendix 8

The device according to any one of Appendixes 1 to 7, in which
the insulating film is hafnia, alumina, or zirconia.

### Appendix 9

The device according to any one of Appendixes 1 to 8, in which
a protective film is disposed on the capacitor.

### Appendix 10

A method for producing a device including:
(a) forming, on a substrate, a capacitor obtained by stacking multilayer films in each of which a first electrode film, an insulating film, and a second electrode film are stacked in this order,
(b) forming a first hole and a second hole penetrating the capacitor in a thickness direction of the capacitor,
(c) forming a first recess along an extending direction of the second electrode film by etching the second electrode film exposed to the first hole,
(d) forming a second recess along an extending direction of the first electrode film by etching the first electrode film exposed to the second hole,
(e) embedding an insulating member in each of the first recess and the second recess, and
(f) embedding a conductor in each of the first hole and the second hole.

### Appendix 11

The method for producing a device according to Appendix 10, in which
the first electrode film and the second electrode film are formed of different materials.

### Appendix 12

The method for producing a device according to Appendix 10 or 11, in which
the first electrode film and the second electrode film are formed of materials capable of being etched at different selectivity ratios.

### Appendix 13

The method for producing a device according to any one of Appendixes 10 to 12, in which
a recess is formed in the substrate, and
in the (a), the first electrode film, the insulating film, and the second electrode film are formed along a shape of the recess.

### Appendix 14

The method for producing a device according to any one of Appendixes 10 to 13, in which
a depth of the first recess in the extending direction of the second electrode film and a depth of the second recess in the extending direction of the first electrode film are both 1 nm or more and 100 nm or less.

### Appendix 15

The method for producing a device according to any one of Appendixes 10 to 14, in which
a thickness of the first electrode film is 1 nm or more and 100 nm or less,
a thickness of the second electrode film is 1 nm or more and 100 nm or less, and
a thickness of the insulating film is 1 nm or more and 100 nm or less.

### Appendix 16

The method for producing a device according to any one of Appendixes 10 to 15, in which
the first electrode film is titanium nitride and
the second electrode film is tungsten.

### Appendix 17

The method for producing a device according to any one of Appendixes 10 to 16, in which
the insulating film is hafnia, alumina, or zirconia.

### Appendix 18

The method for producing a device according to any one of Appendixes 10 to 17, further including:
(g) forming a protective film on the capacitor.

1. A device comprising:
a substrate,
a capacitor disposed on the substrate, the capacitor comprising multilayer films stacked on each other, each of the multilayer films includes a first electrode film, an insulating film stacked on the first electrode film, and a second electrode film stacked on the insulating film, and
a first contact and a second contact penetrating the capacitor in a thickness direction of the capacitor,
a plurality of first insulating members disposed between the first contact and the second electrode films, and
a plurality of second insulating members disposed between the second contact and the first electrode films.

2. The device according to claim 1, wherein:
the first electrode films and the second electrode films are formed of different materials.

3. The device according to claim 1, wherein:
the first electrode films and the second electrode films are formed of materials capable of being etched at different selectivity ratios.

4. The device according to claim 1, wherein
the substrate has a recess, and
for each multilayer film, the first electrode film, the insulating film, and the second electrode film are disposed on the substrate in a shape along the recess.

5. The device according to claim 1, wherein for each multilayer film:
a thickness of the first insulating member in a direction from the first contact toward the second electrode film and a thickness of the second insulating member in a direction from the second contact toward the first electrode film are between 1 nm and 100 nm.

6. The device according to claim 1, wherein for each multilayer film:
a thickness of the first electrode film is between 1 nm and 100 nm,
a thickness of the second electrode film is between 1 nm and 100 nm, and
a thickness of the insulating film is between 1 nm and 100 nm.

7. The device according to claim 1, wherein for each multilayer film:
the first electrode film is titanium nitride, and
the second electrode film is tungsten.

8. The device according to claim 1, wherein for each multilayer film:
the insulating film is hafnia, alumina, or zirconia.

9. The device according to claim 1, wherein
a protective film is disposed on the capacitor.

10. A method for producing a device comprising:
(a) forming, on a substrate, a capacitor obtained by stacking multilayer films, each multilayer film including a first electrode film, an insulating film stacked on the first electrode film, and a second electrode film stacked on the insulating film,
(b) forming a first hole and a second hole penetrating the capacitor in a thickness direction of the capacitor,
(c) forming a first recess along an extending direction of the second electrode films by etching the second electrode film exposed to the first hole,
(d) forming a second recess along an extending direction of the first electrode films by etching the first electrode films exposed to the second hole,
(e) embedding an insulating member in each of the first recess and the second recess, and
(f) embedding a conductor in each of the first hole and the second hole.

11. The method for producing a device according to claim 10, wherein for each multilayer film:
the first electrode film and the second electrode film are formed of different materials.

12. The method for producing a device according to claim 10, wherein for each multilayer film:
the first electrode films and the second electrode films are formed of materials capable of being etched at different selectivity ratios.

13. The method for producing a device according to claim 10, wherein
a recess is formed in the substrate, and
in the (a), the first electrode film, the insulating film, and the second electrode film of each multilayer film are formed along a shape of the recess of the substrate.

14. The method for producing a device according to claim 10, wherein
a depth of the first recess in the extending direction of the second electrode films and a depth of the second recess in the extending direction of the first electrode films are between 1 nm and 100 nm.

15. The method for producing a device according to claim 10, wherein for each multilayer film:
a thickness of the first electrode film is between 1 nm and 100 nm,
a thickness of the second electrode film is between 1 nm and 100 nm, and
a thickness of the insulating film is between 1 nm and 100 nm.

16. The method for producing a device according to claim 10, wherein for each multilayer film:
the first electrode film is titanium nitride, and
the second electrode film is tungsten.

17. The method for producing a device according to claim 10, wherein for each multilayer film:
the insulating film is hafnia, alumina, or zirconia.

18. The method for producing a device according to claim 10, further comprising:
(g) forming a protective film on the capacitor.

19. A device comprising:
a substrate,
a capacitor disposed on the substrate, the capacitor comprising multilayer films stacked on each other, each of the multilayer films includes a first electrode film, an insulating film stacked on the first electrode film, and a second electrode film stacked on the insulating film,
a first contact and a second contact penetrating the capacitor in a thickness direction of the capacitor,
a plurality of first insulating members disposed between the first contact and the second electrode films, an
a plurality of second insulating member disposed between the second contact and the first electrode films, wherein
the substrate has a recess, and
for each multilayer film:
the first electrode film and the second electrode film are formed of materials capable of being etched at different selectivity ratios, and
the first electrode film, the insulating film, and the second electrode film are disposed on the substrate in a shape along the recess of the substrate.

20. The device according to claim 19, wherein
a protective film is disposed on the capacitor.
